(19) United States
(12) Patent Application Publication
(10) Pub. No.: US 2026/0114293 A1
(43) Pub. Date: Apr. 23, 2026

(54) SUBSTRATE WIRING METHOD FOR 2.5D PACKAGING STRUCTURE, SUBSTRATE, AND PACKAGING STRUCTURE

(71) Applicant: FOREHOPE SEMICONDUCTOR (NINGBO) CO., LTD., Ningbo City (CN)

(72) Inventors: Yupeng XU, Ningbo City (CN); Zhenghong HE, Ningbo City (CN)

(21) Appl. No.: 19/188,175

(22) Filed: Apr. 24, 2025

(30) Foreign Application Priority Data
Oct. 22, 2024 (CN) 2024114722312

(51) Int. Cl. H01L 21/48; H01L 23/538

(52) U.S. Cl. CPC H10W 70/05; H10W 70/611; H10W 70/65

(57) ABSTRACT

The present disclosure provides a substrate wiring method for a 2.5D packaging structure, a substrate, and a packaging structure. In the substrate wiring method for a 2.5D packaging structure, the volume V1(i) of each dielectric layer providing a wiring metal layer is calculated, the metal volume V2(i) in each dielectric layer is calculated, and the metal volume ratio K(i) in each dielectric layer is calculated; and

$$K ( i ) = \frac{V 2 ( i )}{V 1 ( i ) + V 2 ( i )} \times 100 \% ,$$

which satisfies |K(i+1)−K(i)|≤8%.

### CROSS-REFERENCE TO RELATED APPLICATIONS

The present disclosure claims the priority to the Chinese patent application with the filling No. 2024114722312 filed with the Chinese Patent Office on Oct. 22, 2024, and entitled “SUBSTRATE WIRING METHOD FOR 2.5D PACKAGING STRUCTURE, SUBSTRATE, AND PACKAGING STRUCTURE”, the contents of which are incorporated herein by reference in entirety.

### TECHNICAL FIELD

The present disclosure relates to the technology field of semiconductors, and specifically, to a substrate wiring method for a 2.5D packaging structure, a substrate, and a packaging structure.

### BACKGROUND ART

With the rapid development of the semiconductor industry, chiplet technology has emerged, providing an arrangement where the chiplets with different functions are packaged together to form a chip packaging structure that is heterogeneously integrated. As the input/output density of chips continues to increase, and the number of chips integrated within a single package increases significantly, 2.5D packaging technology serves as a multi-chip packaging solution that enhances the performance of the packaging structure through a multi-layer wiring layer process. Since the 2.5D packaging structure provides a substrate structure with wiring layers, where the substrate provides a multi-layer wiring layer design, the metal content of the wiring layers in each dielectric layer is inconsistent, and the thermal stress varies, making it prone to delamination between dielectric layers.

### SUMMARY

A substrate wiring method for a 2.5D packaging structure, where the substrate includes multiple stacked dielectric layers, and each dielectric layer respectively provides a wiring metal layer. The substrate wiring method includes:
calculating a volume V1(i) of the dielectric layer that provides the wiring metal layer for each layer, where i is a natural number from 1 to N, and N is a number of dielectric layers that provide the wiring metal layer;
calculating a metal volume V2(i) in each dielectric layer, where i is a natural number from 1 to N, and N is a number of dielectric layers that provide the wiring metal layer; and
calculating a metal volume ratio K(i) in each dielectric layer, where

$$K ( i ) = \frac{V 2 ( i )}{V 1 ( i ) + V 2 ( i )} \times 100 \% , and$$

$$\vert K ( i + 1 ) - K ( i ) \vert \leq 8 \% .$$

A substrate is prepared using the substrate wiring method for a 2.5D packaging structure as provided in any of the foregoing embodiments.

A packaging structure includes components and the substrate as provided in any of the foregoing embodiments, where the components are mounted on the substrate and electrically connected to the substrate.

### BRIEF DESCRIPTION OF DRAWINGS

In order to more clearly illustrate the technical solutions of the embodiments of the present disclosure, the following will briefly introduce the drawings used in the embodiments. It should be understood that the following drawings only show some embodiments of the present disclosure, and therefore it should not be regarded as a limitation on the scope. Those ordinary skilled in the art can also obtain other related drawings based on these drawings without inventive effort.

FIG. 1 is a schematic diagram of a 2.5D packaging structure provided in the embodiment;

FIG. 2 is a schematic diagram of a distribution of a wiring structure in a dielectric layer of a substrate in a 2.5D packaging structure provided in the embodiment;

FIG. 3 is a schematic diagram of a distribution of multiple wiring structures in a dielectric layer of a substrate in a 2.5D packaging structure provided in the embodiment;

FIG. 4 is a schematic diagram of a wiring structure in a substrate of a 2.5D packaging structure provided in the embodiment;

FIG. 5 is a schematic diagram with parameter annotations of a wiring structure in a substrate provided in the embodiment;

FIG. 6 is a schematic diagram of a structure of a substrate in a 2.5D packaging structure provided in the embodiment;

FIG. 7 is a partially enlarged schematic diagram of region F in FIG. 6;

FIG. 8 is a schematic structural diagram of multiple wiring structures with different line widths in a same dielectric layer of a substrate in a 2.5D packaging structure provided in the embodiment;

FIG. 9 is a schematic diagram of a distribution of wiring structures and pseudo wiring layers in a dielectric layer from a sectional perspective of a substrate in a 2.5D packaging structure provided in the embodiment;

FIG. 10 is a schematic diagram of a distribution of wiring structures and pseudo wiring layers in a dielectric layer of a substrate in a 2.5D packaging structure provided in the embodiment;

FIG. 11 is another schematic diagram of a structure of a substrate in a 2.5D packaging structure provided in the embodiment;

FIG. 12 is a schematic diagram of a first structure of a pseudo wiring identification portion formed on a sawing path in a substrate of a 2.5D packaging structure provided in the embodiment;

FIG. 13 is a schematic diagram of a second structure of a pseudo wiring identification portion formed on a sawing path in a substrate of the 2.5D packaging structure provided in the embodiment;

FIG. 14 is a schematic diagram of a third structure of a pseudo wiring identification portion formed on a sawing path in a substrate of a 2.5D packaging structure provided in the present embodiment;

FIG. 15 is a schematic diagram of a distribution structure of a pseudo wiring identification portion on a sawing path in a substrate of a 2.5D packaging structure provided in the embodiment;

FIGS. 16 to 19 are schematic diagrams of a manufacturing process of a substrate in a 2.5D packaging structure provided in the embodiment; and

FIG. 20 is a schematic structural diagram of a 2.5D packaging structure provided in the embodiment from another perspective.

Reference numerals: 10—packaging structure; 100—substrate; 200—chip; 300—encapsulation; 400—substrate board; 110—dielectric layer; 120—wiring metal layer; 1201—wiring structure; 121—first end portion; 122—column section; 123—transition section; 124—connection portion; 125—second end portion; 140—pseudo wiring layer; 141—pseudo wiring layer pattern opening; 143—pseudo wiring identification portion; 150—stress relief portion; 160—bump; 171—carrier; 172—adhesive film layer; 173—photoresist layer; 174—first pattern layer opening; 175—initial metal layer; 111—first dielectric layer; 1111—second pattern layer opening; 131—first wiring metal layer; 112—second dielectric layer; 1121—third pattern layer opening; 132—second wiring metal layer; 113—third dielectric layer; 133—third wiring metal layer; 114—N-th dielectric layer; 134—N-th wiring metal layer; 115—bottom dielectric layer; 116—solder ball; 117—top dielectric layer; 180—sawing path; 181—edge region.

### DETAILED DESCRIPTION OF EMBODIMENTS

In order to make the objectives, technical solutions, and advantages of the embodiments of the present disclosure clearer, the technical solutions in the embodiments of the present disclosure will be clearly and completely described below in conjunction with the drawings in the embodiments of the present disclosure. It is evident that the described embodiments are part of the embodiments of the present disclosure, but not all of the embodiments. The components of the embodiments of the present disclosure described and illustrated in the drawings can typically be arranged and designed in various configurations.

Therefore, the following detailed description of the embodiments of the present disclosure provided in the drawings is not intended to limit the scope of the present disclosure for which protection is claimed, but merely represents selected embodiments of the present disclosure. Based on the embodiments of the present disclosure, all other embodiments obtained by those skilled in the art without inventive effort shall fall within the scope of protection of the present disclosure.

It should be noted that similar numerals and letters denote similar terms in the following drawings so that once an item is defined in one drawing, it does not need to be further discussed in subsequent drawings.

In the description of the present disclosure, it should be noted that the terms “up”, “down”, “inner”, “outer”, and similar directional or positional terms are based on the orientation or positional relationship shown in the drawings, or they represent the customary orientation or positional relationship when the disclosed product is used. These terms are used solely for describing the present disclosure and simplifying the description, and do not indicate or imply that the device or component referred to must have a specific orientation, be constructed and operated in a particular orientation. Therefore, they should not be understood as limiting the scope of the present disclosure.

In addition, terms such as “first”, and “second”, are only used to distinguish the descriptive and are not to be construed as indicating or implying relative importance.

It should be noted that the features in the embodiments of the present disclosure can be combined with each other without conflict.

The objectives of the present disclosure include providing a substrate wiring method for a 2.5D packaging structure, a substrate, and a packaging structure, which can ensure that the metal content in each dielectric layer is generally consistent, so that the thermal expansion coefficients of each layer in the hierarchical structure are similar, thereby reducing warpage deformation and structural delamination caused by thermal stress.

The embodiments of the present disclosure can be implemented as follows.

In a first aspect, the present disclosure provides a substrate wiring method for a 2.5D packaging structure, where the substrate includes multiple stacked dielectric layers, and each dielectric layer respectively provides a wiring metal layer. The substrate wiring method includes:
calculating a volume V1(i) of the dielectric layer that provides the wiring metal layer for each layer, where i is a natural number from 1 to N, and N is a number of dielectric layers that provide the wiring metal layer;
calculating a metal volume V2(i) in each dielectric layer, where i is a natural number from 1 to N, and N is a number of dielectric layers that provide the wiring metal layer; and
calculating a metal volume ratio K(i) in each dielectric layer, where

$$K ( i ) = \frac{V 2 ( i )}{V 1 ( i ) + V 2 ( i )} \times 100 \% , and$$

$$\vert K ( i + 1 ) - K ( i ) \vert \leq 8 \% .$$

In optional embodiments, when N is greater than or equal to 5, then |K(1)−K(N)|≤(N−1)8%.

In an optional embodiment, the wiring metal layer includes a first end portion, a connection portion, and a second end portion that are sequentially connected;

$$V 2 ( i ) = {\sum }_{j = 1}^{m} Vij 1 + Vif 2 + Vij 3 ,$$

where Vij1 represents a volume of the first end portion, Vij2 represents a volume of the connection portion, Vij3 represents a volume of the second end portion, and m represents a number of wiring structures in each wiring metal layer.

In an optional embodiment, the first end portion includes a column section and a transition section that are connected; the transition section is connected to the connection portion; a volume of the first end portion is a sum of a volume of the column section and a volume of the transition section.

In an optional embodiment,

$$V column section = \frac{1}{3} {h}_{1} ( {S}_{1} + {S}_{2} + \sqrt{{S}_{1} {S}_{2}} ) ,$$

where S₁ represents an area of a first top surface of the column section, S₂ represents an area of a first bottom surface of the column section; the first top surface and the first bottom surface are arranged opposite to each other; h₁ represents a height of the column section in a direction perpendicular to the first top surface and the first bottom surface;

$$V transition section = \frac{1}{3} {h}_{2} ( {S}_{3} + {S}_{4} + \sqrt{{S}_{3} {S}_{4}} ) - V overlap 1 ,$$

where S₃ represents an area of a second top surface of the transition section, S₄ represents an area of a second bottom surface of the transition section; the second top surface and the second bottom surface are arranged opposite to each other; h₂ represents a height of the transition section in a direction perpendicular to the second top surface and the second bottom surface, and V overlap 1 represents a volume of an overlapping portion of a column section of the first end portion and the column where the transition section of the first end portion is located;

$$Vij 1 = V column section + V transition section - V overlap 1 ,$$

Vij2=S₃L₁, where L₁ represents a length of the connection portion, and S₃ represents a sectional area of the connection portion;

$$Vij 3 = \frac{1}{3} {h}_{5} ( {S}_{5} + {S}_{6} + \sqrt{{S}_{5} {S}_{6}} ) - V overlap 2 ,$$

where S₅ represents an area of a third top surface of the column of the second end portion, and S₆ represents an area of a third bottom surface of the column of the second end portion; the third top surface and the third bottom surface are arranged opposite to each other; h₅ represents a height of the second end portion in a direction perpendicular to the third top surface and the third bottom surface; and V overlap 2 is the volume of the overlapping portion of the column of the second end portion and the column where the connection portion is located.

In an optional embodiment, if the first top surface of the column section is circular, then S₁=πb², where b is the radius of the circle where the first top surface is located;

$$V overlap 1 = ( \frac{A}{360} {S}_{1} - \frac{1}{2} {b}^{2} sin A ) {h}_{3} ,$$

where A is a central angle corresponding to the overlapping portion of the column section and the column where the transition section is located; and h₃ is a height of the overlapping portion of the column where the transition section is located and the column section in a direction perpendicular to the first top surface.

If the third top surface of the second end portion is circular, then S₅=πd², where d is the radius of the circle where the third top surface is located;

$$V overlap 2 = ( \frac{π {d}^{2} M}{360} - \frac{1}{2} {d}^{2} sin M ) {h}_{4} ,$$

where M is a central angle corresponding to the overlapping portion of the column of the second end portion and the column where the connection portion is located; and h₄ is a height of the overlapping portion of the column of the second end portion and the column where the connection portion is located in a direction perpendicular to the third top surface.

In an optional embodiment, V1(i)=S₇D−V2(i), where S₇ is a bottom area of each dielectric layer, and D is a thickness of each dielectric layer.

In an optional embodiment, if |K(i+1)−K(i)|>8%, then at least one of the following methods is adopted:
1, adding a pseudo wiring layer in the layer with the smaller value of K(i) and K(i+1), where the pseudo wiring layer is made of metal material and the pseudo wiring layer has no electrical connection with the wiring metal layer;
2, reducing the section of at least one of the connection portion, the first end portion, and the second end portion in the layer with the larger value of K(i) and K(i+1); or reducing the number of wiring structures in each wiring metal layer;
3, increasing the section of at least one of the connection portion, the first end portion, and the second end portion in the layer with the smaller value of K(i) and K(i+1); or increasing the number of wiring structures in each wiring metal layer; and
4, increasing the thickness of the dielectric layer in the layer with the larger value of K(i) and K(i+1).

In an optional embodiment, if 40%≥|K(i+1)−K(i)|≥20%, then the pseudo wiring layer is added in the layer with the smaller value of K(i) and K(i+1).

In an optional embodiment, a pseudo wiring layer is added in the i-th layer and the number of wiring structures in the i-th layer is reduced; and wiring structures in a number of that reduced in the i-th layer are added in the (i+1)-th layer and/or the (i−1)-th layer.

In an optional embodiment, a pseudo wiring identification portion is provided in the sawing path of the substrate, and the pseudo wiring identification portion is located on the outermost dielectric layer.

In an optional embodiment, a stress relief portion is provided on the pseudo wiring identification portion of the sawing path.

In an optional embodiment, multiple stress relief portions are provided, and the multiple stress relief portions are arranged in a centrosymmetric distribution; each stress relief portion includes a first edge and a second edge that are arranged opposite to each other, and the first edge and the second edge are symmetrically arranged.

In optional embodiments, the method includes:
forming an initial metal layer;
forming a first dielectric layer covering the initial metal layer, wherein the first dielectric layer is provided with a second pattern layer opening exposing the initial metal layer;
filling metal in the second pattern layer opening to form a first wiring metal layer;
forming a second dielectric layer covering the first wiring metal layer, wherein the second dielectric layer is provided with a third pattern layer opening;
forming a second wiring metal layer in the third pattern layer opening;
repeating the process until forming an (N+1)-th dielectric layer covering the N-th wiring metal layer;
providing a window in the (N+1)-th dielectric layer;
filling metal in the window to form a bump; and
providing a stress balance groove in at least one dielectric layer; filling metal in the stress balance groove; and removing the metal inside the stress balance groove after baking and curing the dielectric layer.

The stress balance groove is provided in the non-mounting region of the substrate, wherein the non-mounting region includes the sawing path and the edge region.

In a second aspect, the present disclosure provides a substrate, which is prepared using the substrate wiring method for a 2.5D packaging structure as provided in any of the foregoing embodiments.

In a third aspect, the present disclosure provides a packaging structure including components and the substrate as provided in any of the foregoing embodiments, where the components are mounted on the substrate and electrically connected to the substrate.

The beneficial effects of the substrate wiring method for a 2.5D packaging structure, the substrate, and the packaging structure provided in the embodiments of the present disclosure include the following.

The substrate wiring method for a 2.5D packaging structure, the substrate, and the packaging structure are provided in the present disclosure, where the substrate adopts a hierarchical structure in which multiple dielectric layers are stacked. Each dielectric layer provides a wiring metal layer. By controlling the metal volume ratio in each dielectric layer, the metal volume ratio difference between two adjacent layers does not exceed 8%. This can ensure that the metal content in each dielectric layer is generally consistent, so that the thermal expansion coefficients of each layer in the hierarchical structure are similar, thereby reducing warpage deformation and structural delamination caused by thermal stress and improving structural reliability.

The embodiments of the present disclosure are further described in detail below with reference to the drawings.

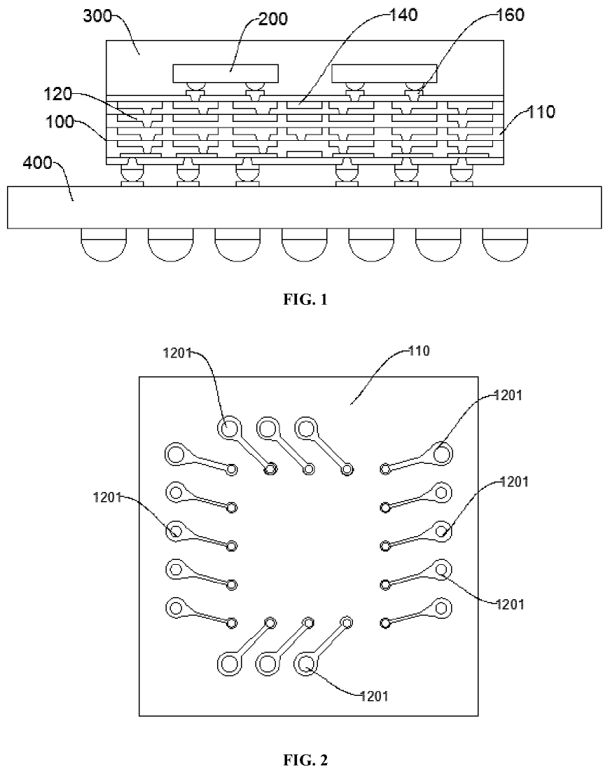

Referring to FIG. 1, the 2.5D packaging structure 10 provided in the embodiments of the present disclosure includes components and a substrate 100. The components are mounted on the substrate 100 and electrically connected to the substrate 100. The components include but are not limited to a chip 200, capacitors, inductors, and resistors. Optionally, the packaging structure 10 includes a substrate board 400, a substrate 100, a chip 200, and an encapsulation 300. The chip 200 is mounted on the substrate 100 and electrically connected to the substrate 100. The encapsulation 300 encapsulates the chip 200 to provide protection. In some embodiments, the encapsulation 300 can be omitted. The substrate 100 includes multiple stacked dielectric layers 110, and each dielectric layer 110 respectively provides a wiring metal layer 120. The substrate 100 is arranged on the substrate board 400, and the substrate 100 and the substrate board 400 are electrically connected.

In the substrate wiring method for a 2.5D packaging structure 10 provided in the embodiments of the present disclosure, the volume V1(i) of each dielectric layer 110 providing a wiring metal layer 120 is calculated, the metal volume V2(i) in each dielectric layer 110 is calculated, and the metal volume ratio K(i) in each dielectric layer 110 is calculated; and

$$K ( i ) = \frac{V 2 ( i )}{V 1 ( i ) + V 2 ( i )} \times 100 \% ,$$

which satisfies |K(i+1)−K(i)|≤8%. This arrangement is beneficial for ensuring that the metal volume ratio in each layer structure is substantially the same, making the thermal expansion coefficients of each layer structure close to each other, reducing warpage and structural delamination caused by thermal stress, and improving structural reliability.

It can be understood that, |K(i+1)−K(i)|≤8%. That is, the metal volume ratio difference between the (i)-th dielectric layer 110 structure and the (i+1)-th dielectric layer 110 structure does not exceed 8%, meaning that the metal volume ratio difference between adjacent dielectric layer 110 structures in the substrate 100 does not exceed 8%. This is beneficial for making the thermal expansion coefficients of adjacent layers in the substrate 100 closer to each other, thereby ensuring that the thermal stress they bear is substantially the same. This can alleviate warpage deformation and structural delamination caused by differences in thermal stress during the manufacturing process.

It should be noted that the dielectric layers 110 controlled for metal volume ratio in the embodiment refer to the dielectric layers 110 providing the wiring metal layers 120. The dielectric layers forming bumps in the upper surface layer and lower surface layer are not within the scope of the above precision control design.

Optionally, when N is greater than or equal to 5, then |K(1)−K(N)|≤(N−1)8%. This means that in the entire substrate 100 structure, the metal volume ratio difference between the first dielectric layer 111 and the Nth dielectric layer 114 does not exceed 8% of (N−1). For example, if there are six dielectric layers 110 providing the wiring metal layers 120, the metal volume ratio difference between the first and sixth layers does not exceed 40%. For example, if there are ten dielectric layers 110 providing the wiring metal layers 120, the metal volume ratio difference between the first and tenth layers does not exceed 72%. This is conducive to achieving a slight difference in the thermal expansion coefficients of the materials of each layer in all hierarchical structures, which in turn helps control warpage deformation of the entire substrate 100 structure during the manufacturing process and reduces the risk of structural delamination.

It can be understood that as N increases, meaning as the number of dielectric layers 110 increases, the cumulative error also increases. By reducing the metal volume ratio difference for one layer and distributing it across multiple layers, the metal volume ratio error between the first layer and the Nth layer is controlled within 8% of (N−1). In this way, the difference in the thermal expansion coefficient of each layer structure is smaller, and the control accuracy is higher, thus effectively mitigating warpage deformation and reducing the risk of structural delamination.

In combination with FIG. 2 to FIG. 4, optionally, the wiring metal layer 120 includes a first end portion 121, a connection portion 124, and a second end portion 125 that are sequentially connected;

$$V 2 ( i ) = {\sum }_{j = 1}^{m} Vij 1 + Vij 2 + Vij 3 ,$$

where Vij1 represents a volume of the first end portion 121, Vij2 represents a volume of the connection portion 124, Vij3 represents a volume of the second end portion 125, and m represents a number of wiring structures in each wiring metal layer 120. In other words, the wiring metal layer 120 within each dielectric layer 110 includes multiple wiring structures 1201, with each wiring structure 1201 including a first end portion 121, a connection portion 124, and a second end portion 125. The volume of each wiring structure 1201 is the sum of the volumes of the first end portion 121, the connection portion 124, and the second end portion 125, represented as Vij1+Vij2+Vij3. The volume of the entire wiring metal layer 120 in the dielectric layer 110 is the sum of the volumes of all wiring structures 1201.

It should be noted that the shape and size of each wiring structure 1201 can be the same or different and can be flexibly designed according to actual requirements. For example, the first end portion 121 can be of any shape, including a truncated cone, a cylinder, a truncated prism, a prism, a cone, or a pyramid. For example, the second end portion 125 can also be of any shape, including a truncated cone, a cylinder, a truncated prism, a prism, a cone, or a pyramid. The connection portion 124 can be of any shape, including a cylinder, an elliptic cylinder, a cuboid, or a semi-cylinder. Each part can have a regular shape or an irregular shape.

It should be understood that some wiring structures 1201 can include multiple connection portions 124. For instance, one first end portion 121 or second end portion 125 can extend into multiple connection portions 124. Alternatively, one connection portion 124 can extend into one or more end portion structures. Regardless of the variations in the shapes of wiring structures 1201, the calculation principle remains the same, which includes computing the volume of each section of every wiring structure 1201 sequentially, summing them, and finally adding up the volumes of multiple wiring structures 1201 of each layer to obtain the total metal volume in the layer.

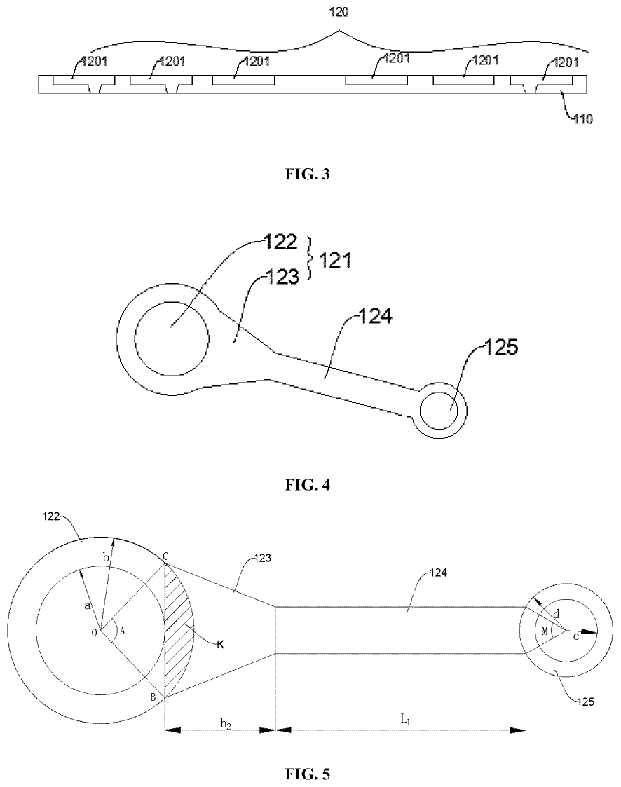

Referring to FIG. 3, FIG. 3 is a schematic diagram of a distribution of wiring metal layer 120 in a dielectric layer 110. It can be seen that some wiring structures 1201 do not have end structures. For example, they can connect two or more wiring structures 1201 in the same layer. Alternatively, some wiring structures 1201 have only one end structure, which is not specifically limited here. Exemplarily, in each wiring structure 1201, the first end portion 121 includes a column section 122 and transition section 123 that are connected, and the transition section 123 is connected to the connection portion 124. The volume of the first end portion 121 is the sum of the volume of the column section 122 and the volume of the transition section 123.

Referring to FIGS. 5 to 7, the volume calculation method of wiring structure 1201 is as follows.

The volume of the column section 122 is calculated as follows:

$$V column section = \frac{1}{3} {h}_{1} ( {S}_{1} + {S}_{2} + \sqrt{{S}_{1} {S}_{2}} ) ,$$

where S₁ is an area of a first top surface of the column section 122, S₂ is an area of a first bottom surface of the column section 122; the first top surface and the first bottom surface are arranged opposite to each other; h₁ is a height of the column section 122 in a direction perpendicular to the first top surface and the first bottom surface.

The volume of the transition section 123 is calculated as follows:

$$V transition section = \frac{1}{3} {h}_{2} ( {S}_{3} + {S}_{4} + \sqrt{{S}_{3} {S}_{4}} ) - V overlap 1 ,$$

where S₃ is an area of a second top surface of the transition section 123, S₄ is an area of a second bottom surface of the transition section 123; the second top surface and the second bottom surface are arranged opposite to each other; h₂ is a height of the transition section 123 in a direction perpendicular to the second top surface and the second bottom surface, and V overlap 1 is a volume of an overlapping portion of a column section 122 of the first end portion 121 and the column where the transition section 123 of the first end portion 121 is located.

The volume of the first end portion 121 is calculated as follows: Vij1=V column section+V transition section−V overlap 1.

The volume of the second end portion 125 is calculated as follows: Vij2=S₅L₁, where L₁ is a length of the connection portion 124, and S₅ is a sectional area of the connection portion 124.

The volume of the third end portion is calculated as follows:

$$Vij 3 = \frac{1}{3} {h}_{5} ( {S}_{5} + {S}_{6} + √ \overline{{S}_{5} {S}_{6}} ) - V overlap 2 ,$$

where S₅ is an area of a third top surface of the column section of the second end portion 125, and S₆ is an area of a third bottom surface of the column section of the second end portion 125; the third top surface and the third bottom surface are arranged opposite to each other; h₅ is a height of the second end portion 125 in a direction perpendicular to the third top surface and the third bottom surface; and V overlap 2 is the volume of the overlapping portion of the column of the second end portion 125 and the column where the connection portion 124 is located.

The volume of each wiring structure 1201 is calculated as follows: V wiring structure=Vij1+Vij2+Vij3.

Optionally, the column section 122 is of a truncated cone structure, the transition section 123 is substantially of a truncated cone structure; the connection portion 124 is cylindrical, and the second end portion 125 is of a truncated cone structure. If the first top surface of the column section 122 is circular, then S₁=πb², where b is the radius of the circle where the first top surface is located. In FIG. 5, a is the radius of the circular first bottom surface, where a<b.

$$V overlap 1 = ( \frac{A}{360} {S}_{1} - \frac{1}{2} {b}^{2} sin A ) {h}_{3} ,$$

where A is a central angle corresponding to the overlapping portion of the column section 122 and the column where the transition section 123 is located; h₃ is a height of the overlapping portion of the column where the transition section 123 is located and the column section 122 in a direction perpendicular to the first top surface.

If the third top surface of the second end portion 125 is circular, then S₅=πd², where d is the radius of the circle where the third top surface is located. In FIG. 5, c is the radius of the circular third bottom surface, where c<d.

$$V overlap 2 = ( \frac{{π d}^{2} M}{360} - \frac{1}{2} {d}^{2} sin M ) {h}_{4} ,$$

where M is a central angle corresponding to the overlapping portion of the column of the second end portion 125 and the column where the connection portion 124 is located, h₄ is a height of the overlapping portion of the column of the second end portion 125 and the column where the connection portion 124 is located in a direction perpendicular to the third top surface.

Referring to FIG. 5, it can be understood that in the above calculation method, there is an overlapping region K between the volume of the column section 122 of the first end portion 121 and the volume of the column where the transition section 123 of the first end portion 121 is located. V overlap 1 represents the volume of the overlapping region. Additionally,

$$V overlap 1 = ( \frac{{π b}^{2} A}{360} - \frac{1}{2} {b}^{2} sin A ) {h}_{3} ,$$

where A is the central angle corresponding to the overlapping region of the prism and the truncated cone, and h₃ is the height corresponding to the overlapping region of the prism and the truncated cone. Optionally, the calculation idea of V overlap 1 is as follows. The sectional area of the overlapping region is obtained by subtracting the area of triangle OCB from the area of the sector region with a radius of b and a central angle of A, which corresponds to the shaded region K in FIG. 5. The product of the sectional area of the overlapping region and the corresponding height is the volume of the region. It should be understood that, depending on different actual shapes, h₃ can be a variable or a fixed value. If it is a variable, the volume of the overlapping region can be calculated using the integral method, and the specific calculation formula is not shown here.

Therefore, the volume of the first end portion 121 is calculated as follows: Vij1=V column section+V transition section−V overlap 1. By substituting the previously mentioned calculation formulas into this formula, the result is:

$${V}_{ij 1} = \frac{1}{3} {π h}_{1} ( {a}^{2} + ab + {b}^{2} ) + \frac{1}{3} {h}_{2} ( {S}_{3} + {S}_{4} + √ \overline{{S}_{3} {S}_{4}} ) - ( \frac{{π b}^{2} A}{360} - \frac{1}{2} {b}^{2} sin A ) {h}_{3} .$$

Vij2=S₃L₁, where L₁ is the length of the connection portion 124. In the present embodiment, the connection portion 124 is taken as an example with a uniform section. The cross-section S₃ of the connection portion 124 is consistent with the area S₃ of the second top surface of the truncated cone in the transition section 123. where S₃<S₄,

and

$$V overlap 2 = ( \frac{{π d}^{2} B}{360} - \frac{1}{2} {d}^{2} sin M ) {h}_{4} ,$$

M is the central angle corresponding to the overlapping region of the connection portion 124 and the truncated cone of the second end portion 125, h₄ is the height corresponding to the overlapping region of the connection portion 124 and the truncated cone of the second end portion 125, and V overlap 2 is the volume of the overlapping region of the truncated cone of the second end portion 125 and the connection portion 124. The calculation idea and method of V overlap 2 are consistent with the calculation idea and method of V overlap 1, and the detailed explanation is omitted here.

If the second end portion 125 is taken as a truncated cone, that is, the third top surface and the third bottom surface are respectively designed as circular, then,

$$Vij 3 = \frac{1}{3} {π h}_{5} ( {c}^{2} + cd + {d}^{2} ) - V overlap 2 ,$$

where c is the radius of the circular third top surface of the truncated cone of the second end portion 125, d is the radius of the circular third bottom surface of the truncated cone of the second end portion 125, where c<d, and h₅ is the height of the truncated cone of the second end portion 125 in the direction perpendicular to the third top surface and the third bottom surface.

It should be understood that to reduce the metal proportion in a layer structure, the volume of at least one of the first end portion 121, the second end portion 125, and the connection portion 124 can be reduced. For example, at least one of S₁, S₂, S₃, S₄, S₅, S₆, h₁, h₂, h₃, h₄, h₅, and L₁ can be reduced. On the contrary, to increase the metal proportion in a layer structure, the volume of at least one of the first end portion 121, the second end portion 125, and the connection portion 124 can be increased. For example, at least one of S₁, S₂, S₃, S₄, S₅, S₆, h₁, h₂, h₃, h₄, h₅, and L₁ can be increased.

In the present embodiment, the column section 122 and the transition section 123 of the first end portion 121 and the second end portion 125 are designed as truncated cone structures, and the connection portion 124 is designed as a cylindrical structure. In other embodiments, the column section 122 and the transition section 123 of the first end portion 121, the second end portion 125, and the connection portion 124 can also have other shapes, which are not specifically limited here.

It should be noted that V2(i) is the sum of the volumes of all metals in each dielectric layer 110. If the dielectric layer 110 only includes the wiring metal layer 120, then V2(i) is the sum of the volumes of all wiring metal layers 120 in the layer. If the dielectric layer 110 includes other metal components in addition to the wiring metal layer 120, then V2(i) is the sum of the volume of all wiring metal layers 120 and the volume of the other metal components in the layer.

Optionally, V1(i)=S₇D−V2(i), where S₇ is a bottom area of each dielectric layer 110, and D is a thickness of each dielectric layer 110.

It is easy to understand that the metal volume ratio and the metal content ratio are consistent. Optionally, if |K(i+1)−K(i)|>8%, that is, if the metal content ratio difference between adjacent dielectric layer structures 110 exceeds a preset value, at least one of the following methods is adopted for adjustment so that the metal content ratio difference between adjacent dielectric layer structures 110 in the final substrate 100 structure does not exceed 8%. The optional adjustment methods are as follows.
1, adding a pseudo wiring layer 140 in the layer with the smaller value of K(i) and K(i+1), where the pseudo wiring layer 140 is made of metal material and the pseudo wiring layer 140 has no electrical connection with the wiring metal layer 120. The pseudo wiring layer 140 is configured to increase the metal content in the layer structure, thereby adjusting the thermal expansion coefficient of the layer and ensuring that the metal content in each layer structure is generally consistent, with uniform thermal stress. This arrangement is beneficial for alleviating warpage deformation and preventing structural delamination. Furthermore, the pseudo wiring layer 140 also serves to enhance structural strength and improve heat dissipation performance.
2, reducing the section of at least one of the connection portion 124, the first end portion 121, and the second end portion 125 in the layer with the larger value of K(i) and K(i+1); or reducing the number of wiring structures in each wiring metal layer 120. This can reduce the metal content in the layer, making the metal content in the layer approximately the same as the metal content in the adjacent layer. That is to say, the metal content ratio of each layer is approximately the same.
3, increasing the section of at least one of the connection portion 124, the first end portion 121, and the second end portion 125 in the layer with the smaller value of K(i) and K(i+1); or increasing the number of wiring structures in each wiring metal layer 120. This can increase the metal content in the layer, making the metal content in the layer approximately the same as the metal content in the adjacent layer.
4, increasing the thickness of the dielectric layer 110 in the layer with the larger value of K(i) and K(i+1). This can also reduce the metal content ratio in the layer.

It should be noted that the preset value in the present embodiment is 8%. In some other embodiments, the preset value can be flexibly set. For example, the preset value can be any value between 0.1% and 8%. Among the above adjustment methods, one or more can be selected for adjustment. The adjustment can be performed only on the layer with a relatively low metal content ratio, or only on the layer with a relatively high metal content ratio. Alternatively, the metal content in both layers can be adjusted simultaneously. By increasing the metal content in the layer with a relatively low metal content ratio and reducing the metal content in the layer with a relatively high metal content ratio, the metal content ratios of the two layers are approximately the same. This is not specifically limited herein.

It can be understood that, in the present embodiment, combined with the above volume calculation method of the wiring structure 1201, the volume of each wiring metal layer 120 before and after adjustment can be accurately calculated. Therefore, the adjustment amount of metal content can be precisely controlled through calculation, which can significantly improve the wiring accuracy and precisely control the metal content in each dielectric layer 110.

Optionally, if 40%≥|K(i+1)−K(i)|≥20%, that is, the difference in metal content ratio between adjacent layers is large, and the difference is between 20% and 40%, a pseudo wiring layer 140 can be added in the layer with the smaller value of K(i) and K(i+1). Adding the pseudo wiring layer 140 can quickly and conveniently increase the metal content in the layer structure.

If the difference in metal content ratio between adjacent layers is relatively small, such as between 8.01% and 19.99%, adjustment can be performed by increasing or decreasing the line width of the wiring layer, increasing or decreasing the number of wiring structures 1201, and other methods. Of course, the adjustment methods mentioned above are not limited to this and are all applicable.

Optionally, a pseudo wiring layer 140 is added in the i-th layer and the number of wiring structures in the i-th layer is reduced; and the number of wiring structures reduced in the i-th layer is added in the (i+1)-th layer and/or the (i−1)-th layer. It can be understood that the volume of each dielectric layer 110 structure is approximately equal, meaning that the space for arranging the wiring metal layer 120 is limited. If a pseudo wiring layer 140 is added in one layer, then the pseudo wiring layer 140 occupies a certain wiring space, which requires sacrificing some wiring structures 1201 in the wiring metal layer 120 of the layer structure. To ensure that the overall number of wiring structures 1201 does not decrease, the wiring structures 1201 can be compensated in the adjacent dielectric layers 110, that is, a corresponding number of wiring structures 1201 can be added to the structure of the adjacent dielectric layer 110.

For example, supposing a pseudo wiring layer 140 is added to the fifth dielectric layer 110 structure, correspondingly, the number of wiring structures 1201 in the fifth dielectric layer 110 structure is reduced by 10, and in the fourth and/or sixth dielectric layer 110 structures, approximately 10 additional wiring structures 1201 are added as compensation. This arrangement increases the structural strength of the fifth dielectric layer 110 and enhances heat dissipation performance. Additionally, reducing the number of wiring structures 1201 in the fifth dielectric layer 110 increases the distance between wiring structures 1201 in the fourth and sixth layers, which helps reduce capacitive effect.

According to the capacitance calculation formula: C=εS/d, where C is the capacitance value, ε is the dielectric constant, S is the projection overlap area of the wiring metal layer 120 in the thickness direction, and d is the vertical distance between wiring metal layers 120 in the thickness direction. It can be seen that reducing the projection overlap area S of the wiring metal layer 120 or increasing the vertical distance between wiring metal layers 120 helps reduce capacitance, thereby lowering capacitive effect. In the present embodiment, since the pseudo wiring layer 140 is provided, it can both increase the vertical distance between wiring metal layers 120 and reduce the projection overlap area of the wiring metal layer 120 in the thickness direction. Thus, it is beneficial for reducing capacitive effect, thereby improving signal transmission speed and reducing crosstalk.

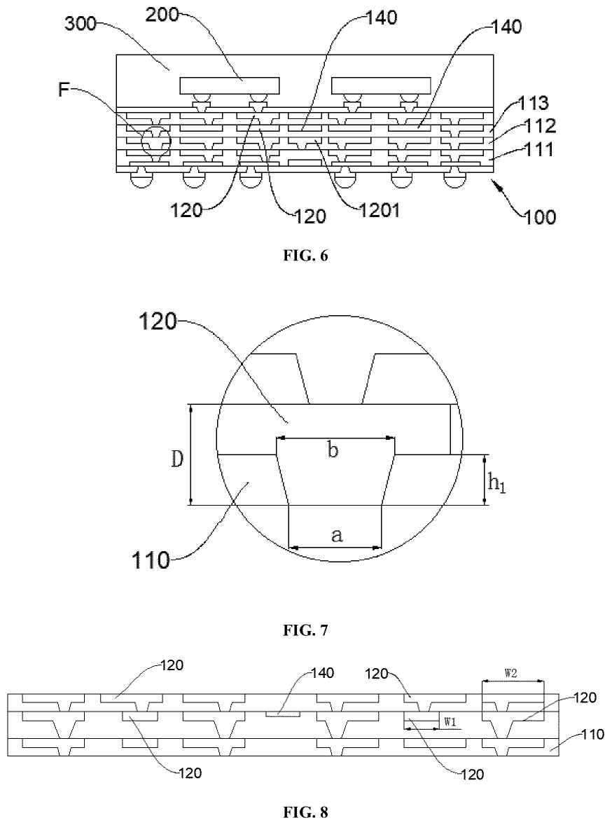

Referring to FIG. 6, in the embodiment, the number of wiring structures 1201 in the third dielectric layer 113 is reduced, and a pseudo wiring layer 140 is provided. In the second dielectric layer 112, the number of wiring structures 1201 is correspondingly increased as compensation. Additionally, the spacing between the fourth wiring metal layer 120 and the second wiring metal layer 132 in the thickness direction is increased, which helps reduce capacitive effect.

It is worth noting that in the sectional view shown in FIG. 6, due to the viewing angle, some pseudo wiring layers 140 and wiring metal layers 120 appear to be connected, but in reality, they are misaligned in the thickness direction and do not have an actual electrical connection.

Referring to FIG. 8, optionally, in the same dielectric layer 110, the wiring metal layer 120 includes multiple wiring structures 1201. The line width, wire diameter, and other parameters of each wiring structure 1201 can be different. For example, some have a thicker line width, as shown by W2 in the figure, and others have a finer line width, as shown by W1. With this arrangement, in regions with finer line widths, the projection overlap area with the wiring metal layer 120 in the adjacent layer is smaller in the thickness direction, which helps reduce capacitive effect, thereby improving signal transmission speed and reducing crosstalk. In high-frequency applications, a smaller line width can improve signal resolution, thereby enhancing circuit performance. Additionally, in cases with smaller line width, the spacing between wiring structures 1201 in the same layer structure can be increased, thereby reducing crosstalk between wiring structures 1201 in the same layer structure.

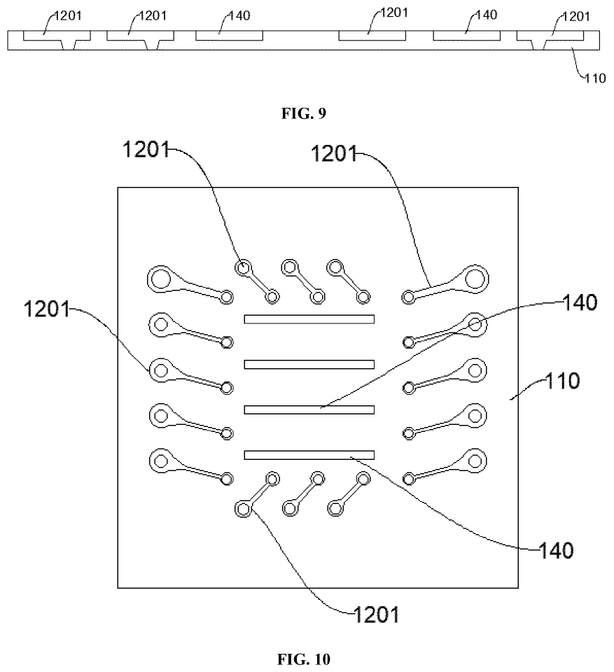

Referring to FIG. 9 and FIG. 10, they illustrate schematic diagrams of distributions of wiring structures 1201 and pseudo wiring layers 140 in a dielectric layer 110 within a layer structure. It is easy to understand that the shape, quantity, and distribution position of the pseudo wiring layer 140 are not specifically limited. The pseudo wiring layer 140, having no electrical connection function, structurally omits end structures. The pseudo wiring layer 140 can include one or more pseudo wiring units, with the shape, size, and distribution position of each unit flexibly configurable. The shapes can be regular or irregular, and parameters such as wire diameter, line width, and length can be flexibly designed based on actual requirements. This is not specifically limited herein.

Referring to FIG. 11, in some embodiments, if the number of wiring structures 1201 in a layer is reduced due to the arrangement of the pseudo wiring layer 140 in the layer, compensation in other layers for the sacrificed wiring structures 1201 is not necessarily required, as long as the metal content in each layer remains approximately uniform without affecting the overall performance of the substrate 100.

Optionally, a pseudo wiring identification portion 143 is arranged on the sawing path 180 of the substrate 100. The pseudo wiring identification portion 143 is positioned on the outermost dielectric layer 110. The pseudo wiring identification portion 143 can enhance the structural strength of the substrate 100 and reduces warpage deformation during the fabrication process. Additionally, it improves heat dissipation performance.

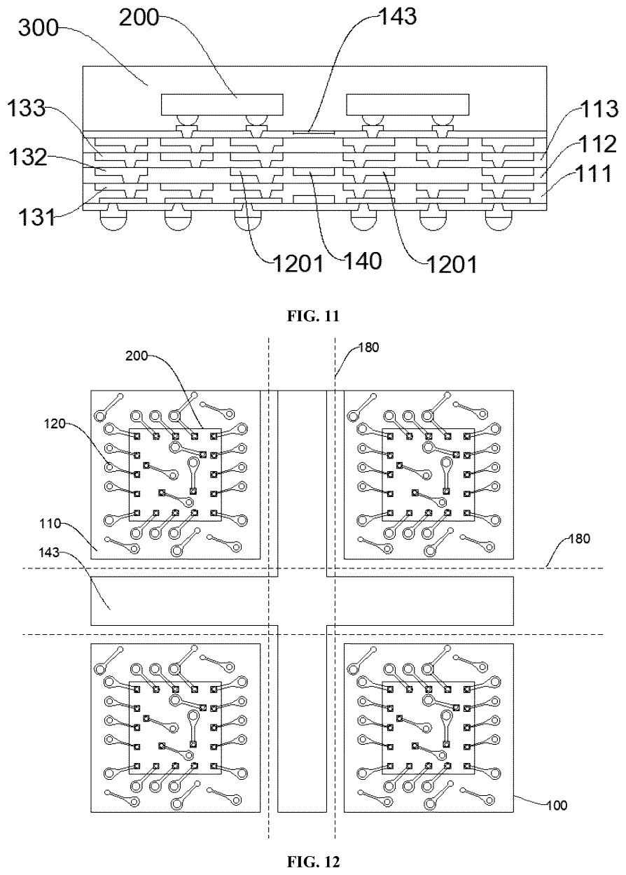

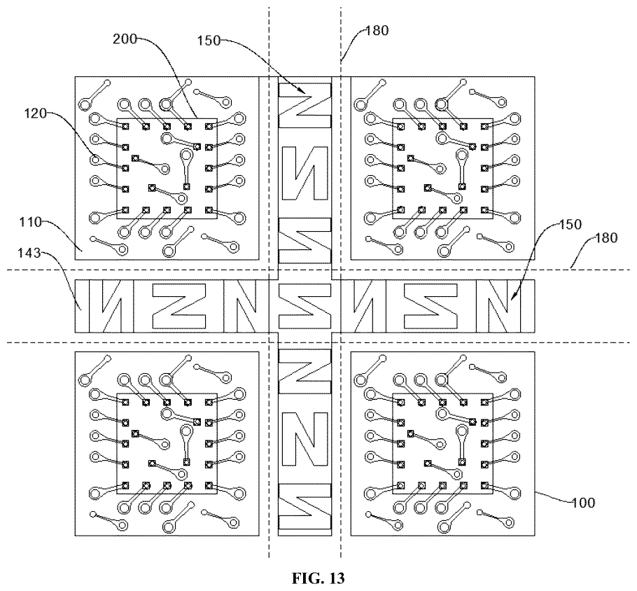

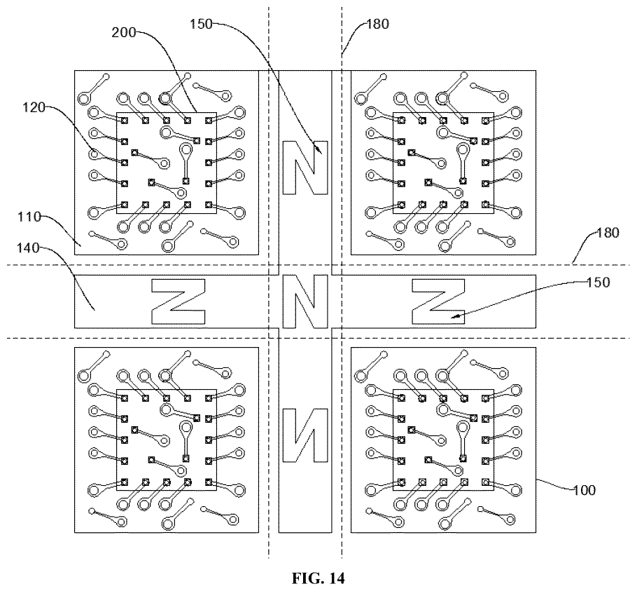

Referring to FIGS. 12 to 14, optionally, a stress relief portion 150 is provided on the pseudo wiring identification portion 143 of the sawing path 180. The stress relief portion 150 is a groove formed in the pseudo wiring identification portion 143. The stress relief portion 150 can be designed in various shapes, including circle, rectangle, diamond, triangle, ellipse, crescent, or any other arbitrary shape. In the embodiment, the section of the stress relief portion 150 is shown as an N-shape or a Z-shape. Of course, it can also take the form of Y-shape, H-shape, L-shape, U-shape, S-shape, T-shape, cross-shape, W-shape, or any other arbitrary shape. The arrangement of the stress relief portion 150 facilitates stress release within the substrate 100, enhances heat dissipation, and improves permeability. Furthermore, the stress relief portion 150 enhances the bonding strength between the substrate 100 and the encapsulation 300 or gel, and the bonding strength between the pseudo wiring identification portion 143 and the dielectric layer 110, thereby ensuring a more reliable structure and preventing delamination.

Optionally, multiple stress relief portions 150 are arranged, and the multiple stress relief portions 150 are arranged in a centrosymmetric manner. The adoption of a symmetric distribution helps balance stress and mitigates structural warpage. It should be understood that in some embodiments, multiple stress relief portions 150 can also be arranged in an axisymmetric manner, without specific limitations here.

Optionally, each stress relief portion 150 includes a first edge and a second edge that are arranged opposite to each other, and the first edge and the second edge are symmetrically arranged. In the embodiment, if the thickness direction of the substrate 100 is taken as the up-down direction, a Z-shaped stress groove is provided on the pseudo wiring identification portion 143 to balance the stress in the front-rear direction, and an N-shaped stress groove is provided on the pseudo wiring identification portion 143 to balance the stress in the left-right direction.

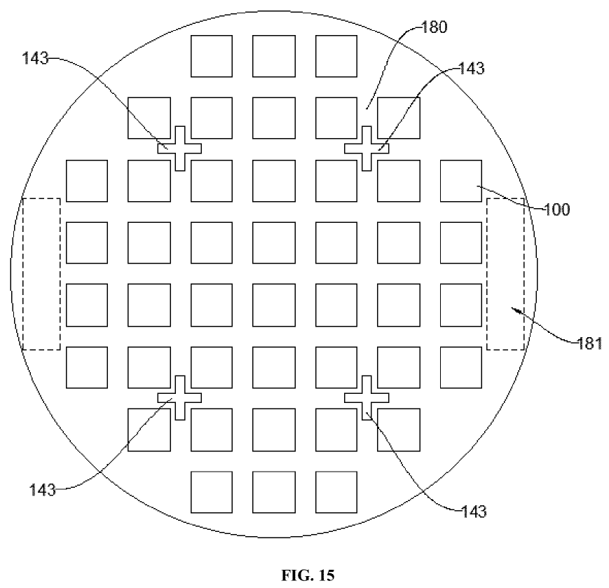

Referring to FIG. 15, optionally, each pseudo wiring identification portion 143 has a cross shape. The intersection of the cross shape is positioned at the junction of the horizontal and vertical sawing paths 180. The pseudo wiring identification portion 143 is only distributed in a part of the sawing path 180 and does not completely cover the sawing path 180. The pseudo wiring identification portion 143 not only enhances strength, improves support performance, reduces warpage deformation, and enhances heat dissipation performance but also serves as an identification and positioning function. For example, it can be configured for positioning recognition and as a positioning reference when mounting the chip 200 onto the substrate 100.

Optionally, a bump 160 is formed in the uppermost dielectric layer 110, and the bump 160 is configured for electrical connection with an external device. In the embodiment, the bump 160 is soldered to a pad on the chip 200 to achieve an electrical connection.

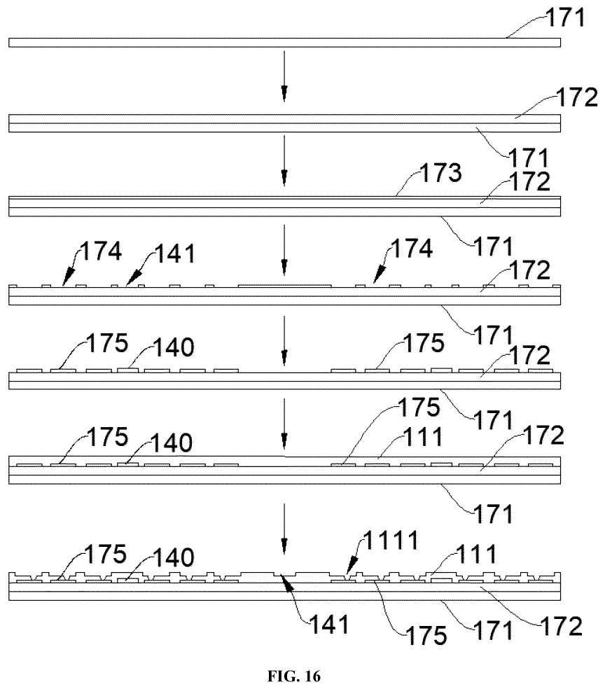

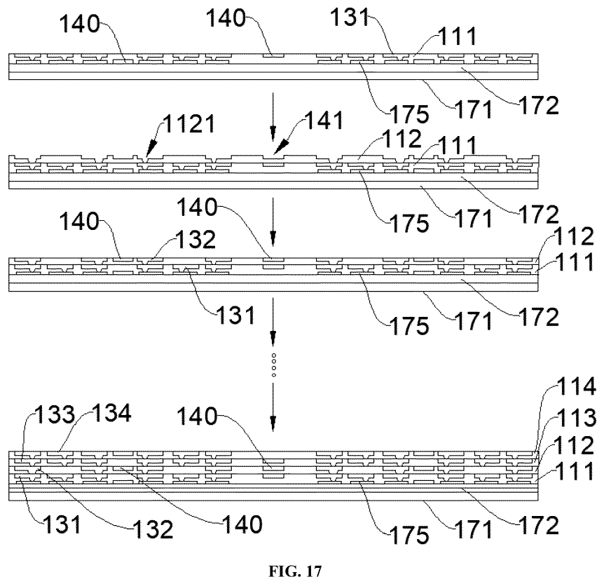

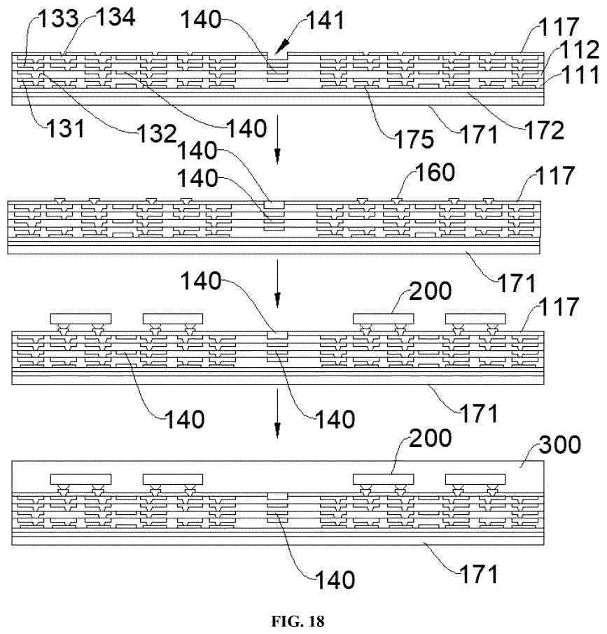

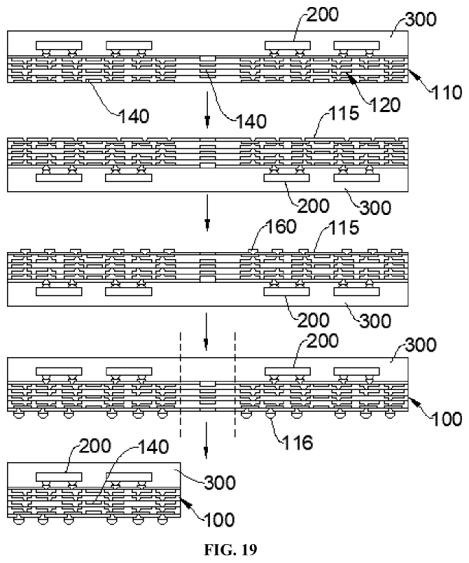

In conjunction with FIGS. 16 to 19, the embodiments of the present disclosure provide a substrate 100, which is prepared using the substrate 100 wiring method for a 2.5D packaging structure 10 as provided in any of the foregoing embodiments. Exemplarily, the preparation method is as follows:
providing a carrier 171, wherein the carrier 171 can be made of materials such as glass, silicon oxide, or metal; and
spin-coating an adhesive film layer 172 onto the carrier 171, wherein the adhesive film layer 172 is made of a thermoplastic material, such as epoxy resin, polyimide, benzocyclobutene, or other polymer composite materials. The adhesive film layer 172 can be separated by ultraviolet (UV) irradiation.
Step S1: spin-coating a photoresist layer 173 onto the adhesive film layer 172; covering a photomask onto the photoresist layer 173, and using an exposure and development process to form a first pattern layer opening 174 in the photoresist layer 173; then, electroplating metal in the first pattern layer opening 174 to form an initial metal layer 175 by using electroplating, sputtering, or chemical plating; and removing the excess photoresist layer 173.
Step S2: spin-coating a first dielectric layer 111 onto the initial metal layer 175, wherein the first dielectric layer 111 covers the initial metal layer 175, and the thickness of the first dielectric layer 111 is greater than the thickness of the initial metal layer 175. Optionally, the dielectric layer 110 can be formed by any process of spin-coating, spraying, printing, physical vapor deposition (PVD), chemical vapor deposition (CVD), metal-organic chemical vapor deposition (MOCVD), atomic layer deposition (ALD), low-pressure chemical vapor deposition (LPCVD), or plasma-enhanced chemical vapor deposition (PECVD). The material of the dielectric layer 110 can be at least one of silicon nitride, silicon oxynitride, polyimide, and benzocyclobutene.
Step S3: covering the photomask onto the first dielectric layer 111 again, and using an exposure and development process to form a second pattern layer opening 1111 in the first dielectric layer 111; and electroplating metal in the second pattern layer opening 1111 to form a first wiring metal layer 131 by using again any process of sputtering, chemical plating, electroplating, physical vapor deposition (PVD), chemical vapor deposition (CVD), metal-organic chemical vapor deposition (MOCVD), atomic layer deposition (ALD), low-pressure chemical vapor deposition (LPCVD), or plasma-enhanced chemical vapor deposition (PECVD).

In the embodiment, since the initial metal layer 175 and the first wiring metal layer 131 are both located within the first dielectric layer 111, the initial metal layer 175 can be regarded as a part of the first wiring metal layer 131. When calculating the metal proportion in the first layer structure, the metal volume is the sum of the volume of the initial metal layer 175 and the volume of the first wiring metal layer 131. Of course, in some embodiments, the initial metal layer 175 can also be omitted, which is not specifically limited herein.

By repeating the above steps S2 and S3, a second dielectric layer 112 covering the first wiring metal layer 131 is formed, wherein the second dielectric layer 112 is provided with a third pattern layer opening 1121. A second wiring metal layer 132 is formed in the third pattern layer opening 1121. By analogy, the process continues until an (N+1)-th dielectric layer covering the N-th wiring metal layer 134 is formed. The (N+1)-th dielectric layer serves as a top dielectric layer 117, in which a window is provided. Metal is filled in the window to form a bump 160.

It can be understood that by repeating the above steps S2 and S3, a second dielectric layer 112, a third pattern layer opening 1121, a second wiring metal layer 132, a third dielectric layer 113, a third wiring metal layer 133, . . . , an Nth dielectric layer 114, and an Nth wiring metal layer 134 are sequentially formed.

Optionally, based on the pre-calculated metal content in each dielectric layer 110, when a pseudo wiring layer 140 needs to be formed, a pseudo wiring layer pattern opening 141 is simultaneously formed by using a photomask when forming the pattern layer opening in each dielectric layer 110. When electroplating metal in the pattern layer opening to form the wiring metal layer 120, metal is simultaneously electroplated in the pseudo wiring layer pattern opening 141 to form the pseudo wiring layer 140.

After forming the N-th wiring metal layer 134, a top dielectric layer 117, namely the (N+1)-th dielectric layer, is further spin-coated. A window is provided in the top dielectric layer 117, and metal is electroplated in the window to form a bump 160. Optionally, a cross-shaped pseudo wiring identification portion 143 is formed on the top dielectric layer 117. A hollow stress relief portion 150, such as an N-shaped groove or a Z-shaped groove, is etched on the pseudo wiring identification portion 143, and thus, stress relief and identification are achieved.

Optionally, in the above preparation method of the substrate 100, a stress balancing groove is provided on any one layer, any multiple layers, or each dielectric layer 110. Metal is filled into the stress balancing groove. After baking and curing the dielectric layer 110, the metal in the stress balancing groove is removed. The metal in the stress balancing groove is not electrically connected to the wiring metal layer 120. One or more stress balancing grooves are spaced apart from the wiring metal layer 120 in the dielectric layer 110 and can be arranged at any position of the dielectric layer 110. Optionally, one or more stress balancing grooves are preferably distributed at positions corresponding to the sawing path 180 or in the edge region 181 of the dielectric layer 110, which are non-mounting regions. This prevents etching interfaces or marks from being left in the wiring region of the substrate 100, which helps improve wiring precision. At the same time, it can effectively resist baking thermal stress, thereby reducing structural warpage and deformation caused by baking thermal stress, making the surface of the substrate 100 flatter and the structure more reliable.

Optionally, a micro-etching process is used to remove the metal in the stress balancing groove. This can form a micro-etched groove on the surface of the dielectric layer 110, which improves the bonding strength between multilayer structures and enhances structural reliability when another dielectric layer 110 is coated on it.

Since in each layer structure, the metal in the stress balancing groove is removed using a micro-etching process after each baking process is completed, this can both counteract baking stress and avoid affecting the metal content in the overall structure.

The chip 200 is mounted onto the bump 160. The solder joints of the chip 200 are soldered to the bumps 160 on the substrate 100. After mounting the chip 200, the bottom of the chip 200 is filled with the underfill. The number and types of mounted chips 200 can be flexibly set according to actual conditions. The chip 200 is encapsulated, and an encapsulation 300 covering the chip 200 is formed on one side of the substrate 100. After curing the encapsulation 300, the carrier 171 is removed.

A dielectric layer 110 is spin-coated on the side of the substrate 100 where the carrier 171 is removed, serving as a bottom dielectric layer 115. An opening is formed in the bottom dielectric layer 115, and the metal is arranged in the opening to form the bump 160 on the other side of the substrate 100. A bumping process is performed on the bump 160 on the side to form a solder ball 116. Finally, individual products are formed by sawing and separating.

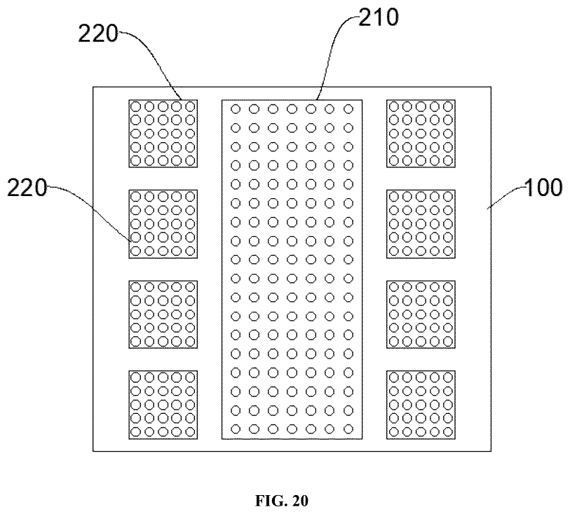

In conjunction with FIG. 20, in the embodiment, the chips 200 mounted on the substrate 100 are not limited to one type and can include multiple types. For example, the chips 200 include a first chip and a second chip of different types. The first chip and the second chip are respectively mounted on the substrate 100.

In summary, the beneficial effects of the substrate wiring method for a 2.5D packaging structure 10, the substrate 100, and the packaging structure 10 provided in the embodiments of the present disclosure have the following beneficial effects.

The substrate wiring method for a 2.5D packaging structure 10, the substrate 100, and the packaging structure 10 are provided in the present disclosure, where the substrate 100 adopts a hierarchical structure in which multiple dielectric layers 110 are stacked. Each dielectric layer 110 provides a wiring metal layer 120. By controlling the metal volume ratio in each dielectric layer 110, the metal volume ratio difference between two adjacent layers does not exceed 8%. This can ensure that the metal content in each dielectric layer 110 is generally consistent, so that the thermal expansion coefficients of each layer in the hierarchical structure are similar, thereby reducing warpage deformation and structural delamination caused by thermal stress and improving structural reliability. Additionally, the design of the pseudo wiring layer 140 facilitates controlling the metal content in each layer structure, enhancing structural strength, and alleviating warpage deformation. It improves heat dissipation performance, and also helps balance thermal stress during the process and maintains the flatness of the substrate 100 structure.

The above are just specific embodiments of the present disclosure, but the scope of protection of the present disclosure is not limited to the embodiments. Any variations or substitutions, readily apparent to those skilled in the art within the technical scope disclosed in the present disclosure, should be encompassed within the scope of protection of the present disclosure.

### INDUSTRIAL PRACTICALITY

The substrate wiring method for a 2.5D packaging structure, the substrate, and the packaging structure are provided in the present disclosure, where the substrate adopts a hierarchical structure in which multiple dielectric layers are stacked. Each dielectric layer provides a wiring metal layer. By controlling the metal volume ratio in each dielectric layer, the metal volume ratio difference between two adjacent layers does not exceed 8%. This can ensure that the metal content in each dielectric layer is generally consistent, so that the thermal expansion coefficients of each layer in the hierarchical structure are similar, thereby reducing warpage deformation and structural delamination caused by thermal stress and improving structural reliability.

1. A substrate wiring method for a 2.5D packaging structure, wherein the substrate comprises multiple stacked dielectric layers, and each dielectric layer respectively provides a wiring metal layer; and the substrate wiring method comprises:
calculating a volume V1(i) of the dielectric layer that provides the wiring metal layer for each layer;
calculating a metal volume V2(i) in each dielectric layer, where i is a natural number from 1 to N, and N is a number of dielectric layers that provide the wiring metal layer; and
calculating a metal volume ratio K(i) in each dielectric layer, where
$$K ( i ) = \frac{V 2 ( i )}{V 1 ( i ) + V 2 ( i )} \times 100 \% , and$$
$$\vert K ( i + 1 ) - K ( i ) \vert \leq 8 \% .$$

2. The substrate wiring method for a 2.5D packaging structure according to claim 1, wherein when N is greater than or equal to 5, then |K(1)−K(N)|≤(N−1)8%.

3. The substrate wiring method for a 2.5D packaging structure according to claim 1, wherein the wiring metal layer comprises a first end portion, a connection portion, and a second end portion that are sequentially connected;
$$V 2 ( i ) = {\sum }_{j = 1}^{m} Vij 1 + Vij 2 + Vij 3 ,$$
where Vij1 represents a volume of the first end portion, Vij2 represents a volume of the connection portion, Vij3 represents a volume of the second end portion, and m represents a number of wiring structures in each wiring metal layer.

4. The substrate wiring method for a 2.5D packaging structure according to claim 3, wherein the first end portion comprises a column section and a transition section that are connected; the transition section is connected to the connection portion; and a volume of the first end portion is a sum of a volume of the column section and a volume of the transition section.

5. The substrate wiring method for a 2.5D packaging structure according to claim 4, wherein
$$V column section = \frac{1}{3} {h}_{1} ( {S}_{1} + {S}_{2} + √ \overline{{S}_{1} {S}_{2}} ) ,$$
where S₁ is an area of a first top surface of the column section, S₂ is an area of a first bottom surface of the column section, the first top surface and the first bottom surface are arranged opposite to each other, and h₁ is a height of the column section in a direction perpendicular to the first top surface and the first bottom surface;
$$V transition section = \frac{1}{3} {h}_{2} ( {S}_{3} + {S}_{4} + √ \overline{{S}_{3} {S}_{4}} ) - V overlap 1 ,$$
where S₃ is an area of a second top surface of the transition section, S₄ is an area of a second bottom surface of the transition section, the second top surface and the second bottom surface are arranged opposite to each other, h₂ is a height of the transition section in a direction perpendicular to the second top surface and the second bottom surface, and V overlap 1 is a volume of an overlapping portion of the column section of the first end portion and a column where the transition section of the first end portion is located;
Vij1=V column section+V transition section−V overlap 1;
Vij2=S₅L₁, where L₁ is a length of the connection portion, and S₅ is a sectional area of the connection portion; and
$$Vij 3 = \frac{1}{3} {h}_{5} ( {S}_{5} + {S}_{6} + √ \overline{{S}_{5} {S}_{6}} ) - V overplap 2 ,$$
where S₅ is an area of a third top surface of a column of the second end portion, S₆ is an area of a third bottom surface of the column of the second end portion, the third top surface and the third bottom surface are arranged opposite to each other, h₅ is a height of the second end portion in a direction perpendicular to the third top surface and the third bottom surface, and V overlap 2 is a volume of an overlapping portion of the column of the second end portion and a column where the connection portion is located.

6. The substrate wiring method for a 2.5D packaging structure according to claim 5, wherein when the first top surface of the column section is circular, then S₁=πb², where b is a radius of a circle where the first top surface is located;
$$V overlap 1 = ( \frac{A}{360} {S}_{1} - \frac{1}{2} {b}^{2} sin A ) {h}_{3} ,$$
where A is a central angle corresponding to the overlapping portion of the column section and the column where the transition section is located; h₃ is a height of the overlapping portion of the column where the transition section is located and the column section in a direction perpendicular to the first top surface;
when the third top surface of the second end portion is circular, then S₅=πd², where d is a radius of a circle where the third top surface is located; and
$$V overlap 2 = ( \frac{{π d}^{2} M}{360} - \frac{1}{2} {d}^{2} sin M ) {h}_{4} ,$$
where M is a central angle corresponding to the overlapping portion of the column of the second end portion and the column where the connection portion is located, and h₄ is a height of the overlapping portion of the column of the second end portion and the column where the connection portion is located in a direction perpendicular to the third top surface.

7. The substrate wiring method for a 2.5D packaging structure according to claim 1, wherein V1(i)=S₇D−V2(i), where S₇ is a bottom area of each dielectric layer, and D is a thickness of each dielectric layer.

8. The substrate wiring method for a 2.5D packaging structure according to claim 1, wherein when satisfying |K(i+1)−K(i)|>8%, then at least one of following methods is adopted for adjustment:
1, adding a pseudo wiring layer in a layer with a smaller value of K(i) and K(i+1), where the pseudo wiring layer is made of metal material and the pseudo wiring layer has no electrical connection with the wiring metal layer;
2, reducing a section of at least one of the connection portion, the first end portion, and the second end portion in a layer with a larger value of K(i) and K(i+1); or reducing a number of wiring structures in each wiring metal layer;
3, increasing the section of at least one of the connection portion, the first end portion, and the second end portion in the layer with the smaller value of K(i) and K(i+1); or increasing the number of wiring structures in each wiring metal layer; and
4, increasing a thickness of the dielectric layer in the layer with the larger value of K(i) and K(i+1).

9. The substrate wiring method for a 2.5D packaging structure according to claim 8, wherein when satisfying 40%≥|K(i+1)−K(i)|≥20%, then the pseudo wiring layer is added in the layer with the smaller value of K(i) and K(i+1).

10. The substrate wiring method for a 2.5D packaging structure according to claim 1, wherein a pseudo wiring layer is added in an i-th layer and the number of wiring structures in the i-th layer is reduced; and wiring structures in a number of that reduced in the i-th layer are added in an (i+1)-th layer and/or an (i−1)-th layer.

11. The substrate wiring method for a 2.5D packaging structure according to claim 1, wherein a pseudo wiring identification portion is provided in a sawing path of the substrate, and the pseudo wiring identification portion is located on an outermost dielectric layer.

12. The substrate wiring method for a 2.5D packaging structure according to claim 11, wherein a stress relief portion is provided on the pseudo wiring identification portion of the sawing path.

13. The substrate wiring method for a 2.5D packaging structure according to claim 12, wherein multiple stress relief portions are arranged, and the multiple stress relief portions are arranged in a centrosymmetric manner; and
each stress relief portion comprises a first edge and a second edge that are arranged opposite to each other, and the first edge and the second edge are symmetrically arranged.

14. The substrate wiring method for a 2.5D packaging structure according to claim 1, comprising:
forming an initial metal layer;
forming a first dielectric layer covering the initial metal layer, wherein the first dielectric layer is provided with a second pattern layer opening exposing the initial metal layer;
filling metal in the second pattern layer opening to form a first wiring metal layer;
forming a second dielectric layer covering the first wiring metal layer, wherein the second dielectric layer is provided with a third pattern layer opening;
forming a second wiring metal layer in the third pattern layer opening;
repeating the process until forming an (N+1)-th dielectric layer covering an N-th wiring metal layer;
providing a window in the (N+1)-th dielectric layer; filling metal in the window to form a bump; and
providing a stress balance groove in at least one dielectric layer; filling metal in the stress balance groove; and removing the metal inside the stress balance groove after baking and curing the dielectric layer.

15. The substrate wiring method for a 2.5D packaging structure according to claim 14, wherein the stress balance groove is provided in a non-mounting region of the substrate, and the non-mounting region comprises the sawing path and an edge region.

16. A substrate, prepared using the substrate wiring method for a 2.5D packaging structure according to claim 1.

17. A packaging structure, comprising components and the substrate according to claim 16, wherein the components are mounted on the substrate and electrically connected to the substrate.

18. The substrate according to claim 16, wherein when N is greater than or equal to 5, then |K(1)−K(N)|≤(N−1)8%.

19. The substrate according to claim 16, wherein the wiring metal layer comprises a first end portion, a connection portion, and a second end portion that are sequentially connected;
$$V 2 ( i ) = {\sum }_{j = 1}^{m} Vij 1 + Vij 2 + Vij 3 ,$$
where Vij1 represents a volume of the first end portion, Vij2 represents a volume of the connection portion, Vij3 represents a volume of the second end portion, and m represents a number of wiring structures in each wiring metal layer.

20. The substrate according to claim 19, wherein the first end portion comprises a column section and a transition section that are connected; the transition section is connected to the connection portion; a volume of the first end portion is a sum of a volume of the column section and a volume of the transition section.
